(19) United States
(12) Patent Application Publication
(10) Pub. No.: US 2026/0236413 A1
(43) Pub. Date: Aug. 13, 2026

(54) NON-VOLATILE MEMORY DEVICE, STORAGE DEVICE INCLUDING THE SAME AND OPERATING METHOD OF NON-VOLATILE MEMORY DEVICE

(71) Applicant: Samsung Electronics Co., Ltd., Suwon-si (KR)

(72) Inventors: Youngmin JO, Suwon-si (KR); Sang-Lok KIM, Suwon-si (KR); Taehyeon PARK, Suwon-si (KR); Chiweon YOON, Suwon-si (KR)

(21) Appl. No.: 19/422,634

(22) Filed: Dec. 17, 2025

(30) Foreign Application Priority Data
Feb. 12, 2025 (KR) 10-2025-0018292

(51) Int. Cl. G06F 13/28; G06F 13/16; G06F 13/40

(52) U.S. Cl. CPC G06F 13/28; G06F 13/1668; G06F 13/4068

(57) ABSTRACT

A storage device includes a plurality of non-volatile memory devices, each including a CA pin, a data pin, and a data burst pin, and a storage controller configured to transmit a command through the CA pin, transmit and receive data through the data pin, and transmit a data burst enable signal and a data burst disable signal through the data burst pin. Among the plurality of non-volatile memory devices, a target non-volatile memory device performs a memory access operation based on a memory access command received while receiving a first data burst enable signal, and based on a second data burst enable signal. Among the plurality of non-volatile memory devices, a non-target non-volatile memory device performs an on-die termination activation operation based on the memory access command and the second data burst enable signal.

### CROSS-REFERENCE TO RELATED APPLICATION

This application claims priority to Korean Patent Application No. 10-2025-0018292, filed in the Korean Intellectual Property Office on February 12, 2025, the entire contents of which are hereby incorporated by reference.

### BACKGROUND

The present disclosure relates to a non-volatile memory device, a storage device including the non-volatile memory device, and an operating method of the non-volatile memory device.

Semiconductor memory devices may be classified into volatile memory devices such as static RAM (SRAM), dynamic RAM (DRAM), synchronous DRAM (SDRAM) in which stored data is lost when power supply is cut off, and non-volatile memory devices such as read-only memory (ROM), programmable ROM (PROM), electrically programmable ROM (EPROM), electrically erasable and programmable ROM (EEPROM), flash memory devices, phase-change RAM (PRAM), magnetic RAM (MRAM), resistive RAM (RRAM), ferroelectric RAM (FRAM), and so on, which may retain stored data even when the power supply is interrupted.

Meanwhile, an on-die termination (ODT) technique may be utilized to maintain signal integrity. ODT may serve to suppress signal reflection that may occur during data transmission, thereby supporting stable signal transmission. However, data transmission may be temporarily suspended, or additional delay may occur during the ODT control process, which can limit the overall data transmission speed.

The above information is provided to enhance the understanding of the background of the present disclosure, and may include information that does not constitute the related art.

### SUMMARY

The present disclosure relates to a non-volatile memory device, a storage device including the same, and an operating method of the non-volatile memory device, which address the foregoing issues.

The problems to be solved by the present disclosure are not limited to those described above, and other problems not mentioned will be clearly understood by those skilled in the art from the following description of embodiments.

In some embodiments, a storage device may include a plurality of non-volatile memory devices, each of the plurality of non-volatile memory devices including a CA (command and address) pin, a data (DQ) pin, and a data burst pin, and a storage controller configured to transmit a command through the CA pin, transmit and receive data through the data pin, and transmit a data burst enable signal and a data burst disable signal through the data burst pin of the plurality of non-volatile memory devices. Among the plurality of non-volatile memory devices, a target non-volatile memory device is configured to perform a memory access operation based on a memory access command received while receiving a first data burst enable signal, and based on a second data burst enable signal. Among the plurality of non-volatile memory devices, a non-target non-volatile memory device is configured to perform an on-die termination (ODT) activation operation based on the memory access command and the second data burst enable signal. The plurality of non-volatile memory devices is configured to receive the second data burst enable signal after receiving the first data burst enable signal.

In some embodiments, a non-volatile memory device may include a data input/output circuit configured to transmit and receive data to and from a storage controller through a data (DQ) pin, a memory cell array including a plurality of memory cells, and control logic configured to receive a command from the storage controller through a CA pin, and configured to receive a data burst enable signal and a data burst disable signal from the storage controller through a data burst pin, wherein the control logic is further configured to receive a memory access command through the CA pin while receiving a first data burst enable signal through the data burst pin, after receiving the first data burst enable signal, receive a second data burst enable signal through the data burst pin, and based on the memory access command and the second data burst enable signal, perform a memory access operation as a target non-volatile memory device or perform an ODT activation operation as a non-target non-volatile memory device.

In some embodiments, a method of operating a non-volatile memory device may include receiving, from a storage controller through a data burst pin, a first data burst enable signal, receiving, from the storage controller through a CA pin while receiving the first data burst enable signal, a memory access command, receiving, from the storage controller through the data burst pin, a second data burst enable signal after the first data burst enable signal is received, and based on the memory access command and the second data burst enable signal, performing a memory access operation as a target non-volatile memory device or performing an ODT activation operation as a non-target non-volatile memory device.

The effects obtainable through the present disclosure are not limited to those described above. Other technical effects not mentioned will be clearly understood by those skilled in the art from the following detailed description.

### BRIEF DESCRIPTION OF THE DRAWINGS

FIG. 1 illustrates a block diagram of a storage system according to some embodiments of the present disclosure.

FIG. 2 illustrates a block diagram of a storage device according to some embodiments of the present disclosure.

FIG. 3 illustrates a block diagram of a storage device according to some embodiments of the present disclosure.

FIG. 4 illustrates a block diagram of a non-volatile memory device according to some embodiments of the present disclosure.

FIG. 5 is a diagram illustrating a non-volatile memory device according to some embodiments of the present disclosure.

FIG. 6 is a diagram illustrating the configuration of a control block according to some embodiments of the present disclosure.

FIG. 7 is a diagram showing data transmission/reception processes and signal timings between a storage controller and a plurality of non-volatile memory devices according to some embodiments of the present disclosure.

FIG. 8 is a diagram illustrating operations performed when data burst enable signals and data burst disable signals are received, according to commands and decoded commands received by a non-volatile memory device.

FIG. 9 is a diagram illustrating a non-volatile memory device according to some embodiments of the present disclosure.

FIG. 10 is a diagram illustrating a signal flow when a write command is received, according to some embodiments of the present disclosure.

FIG. 11 is a diagram illustrating a signal flow when a read command is received, according to some embodiments of the present disclosure.

FIG. 12 is a diagram illustrating a signal flow during an ODT activation operation according to some embodiments of the present disclosure.

FIG. 13 is a diagram illustrating an operation performed when a data burst disable signal is received, according to some embodiments of the present disclosure.

FIG. 14 is a diagram illustrating a non-volatile memory device according to some embodiments of the present disclosure.

FIG. 15 is a diagram illustrating data transmission/reception processes and signal timings between a storage controller and a plurality of non-volatile memory devices according to some embodiments of the present disclosure.

FIG. 16 is a diagram illustrating a non-volatile memory device according to some embodiments of the present disclosure.

FIG. 17 is a diagram illustrating data transmission/reception processes and signal timings between a storage controller and a plurality of non-volatile memory devices according to some embodiments of the present disclosure.

FIG. 18 is a flowchart illustrating a method of operating a non-volatile memory device according to some embodiments of the present disclosure.

FIG. 19 is a block diagram illustrating an example in which a storage device is applied to an SSD system according to some embodiments of the present disclosure.

### DETAILED DESCRIPTION

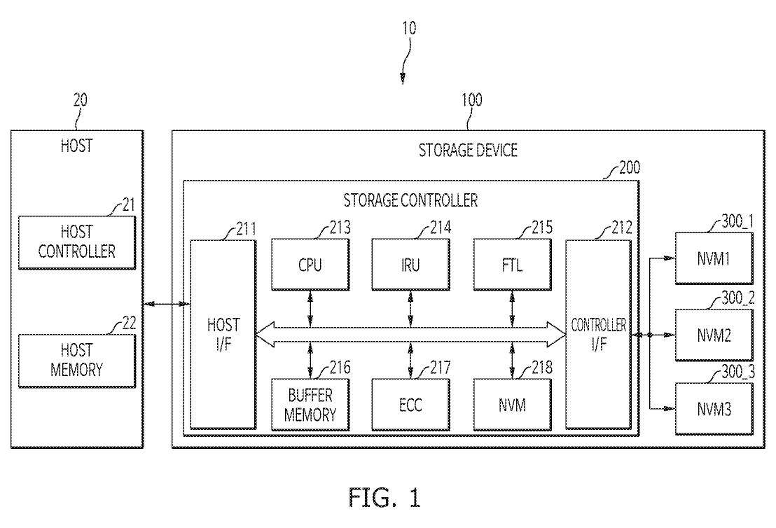

Hereinafter, various embodiments of the present disclosure will be described with reference to FIGS. 1 through 19. Identical reference numerals across the specification may refer to identical or substantially similar components.

FIG. 1 illustrates a block diagram of a storage system according to some embodiments of the present disclosure. Referring to FIG. 1, a storage system 10 may include a host 20 and a storage device 100.

The host 20 may include a host controller 21 and a host memory 22. The host memory 22 may function as a buffer memory for temporarily storing data to be transferred to the storage device 100 or data transferred from the storage device 100.

In some embodiments, the host controller 21 and the host memory 22 may be implemented as separate semiconductor chips. In some embodiments, the host controller 21 and the host memory 22 may be integrated in the same semiconductor chip. For example, the host controller 21 may be any one of multiple modules included in an application processor, and the application processor may be implemented as a system on chip (SoC). Further, the host memory 22 may be embedded memory included in the application processor, or may be a volatile memory or memory module placed outside of the application processor.

The host controller 21 may manage an operation of storing data (e.g., write data) of the host memory 22 in the non-volatile memory devices 300_1, 300_2, and 300_3, or an operation of storing data (e.g., read data) of the non-volatile memory devices 300_1, 300_2, and 300_3 in the host memory 22. For example, the host controller 21 may manage an operation of storing user data associated with execution of a specific program in the non-volatile memory devices 300_1, 300_2, and 300_3.

The storage device 100 may include a storage controller 200 and a plurality of non-volatile memory devices 300_1, 300_2, and 300_3.

The storage device 100 may include a storage medium for storing data in response to a request from the host 20. For example, the storage device 100 may include at least one of an SSD (solid state drive), embedded memory, or removable external memory. When the storage device 100 is an SSD, it may follow the NVMe (non-volatile memory express) standard. When the storage device 100 is an embedded memory or an external memory, it may follow the UFS (universal flash storage) or eMMC (embedded multi-media card) standard. The host 20 and the storage device 100 may each generate and transmit packets in accordance with an adopted standard protocol.

When the non-volatile memory devices 300_1, 300_2, and 300_3 include a flash memory, the flash memory may include a 2D NAND memory array or a 3D (or vertical, bonding-vertical (Bonding Vertical)) NAND (VNAND) memory array. In some examples, the storage device 100 may also include various other types of non-volatile memory and/or volatile memory. For instance, the storage device 100 may include at least one of SRAM (static RAM), DRAM (dynamic RAM), SDRAM (synchronous DRAM), ROM (read only memory), PROM (programmable ROM), EPROM (electrically programmable ROM), EEPROM (electrically erasable and programmable ROM), MRAM (magnetic RAM), spin-transfer torque MRAM, conductive bridging RAM (CBRAM), FeRAM (ferroelectric RAM), PRAM (phase-change RAM), resistive RAM, and so on, which may be volatile or non-volatile memory. At least some of the plurality of non-volatile memory devices 300_1, 300_2, and 300_3 may be volatile memory devices.

The storage controller 200 may include a host interface 211, a controller interface circuit 212, and a CPU (central processing unit) 213. In addition, the storage controller 200 may further include an index read unit (IRU) 214, a flash translation layer (FTL) 215, a buffer memory 216, an ECC (error correction code) engine 217, and an internal non-volatile memory 218. The storage controller 200 may also include working memory in which the flash translation layer 215 is loaded, and by executing the flash translation layer 215, the CPU 213 may control data write and read operations on the non-volatile memory. For example, by executing the flash translation layer 215, the CPU 213 may control a write operation of user data to the non-volatile memory devices 300_1, 300_2, and 300_3.

The host interface 211 may transmit/receive packets to/from the host 20. The packet transmitted from the host 20 to the host interface 211 may include a command and/or data (e.g., user data) to be written in the non-volatile memory devices 300_1, 300_2, and 300_3, and the packet transmitted from the host interface 211 to the host 20 may include a response to the command or data read from the non-volatile memory devices 300_1, 300_2, and 300_3, and so on. Although the host interface 211 is shown as included in the storage controller 200, it is not limited thereto. For example, the host interface 211 may be located outside the storage controller 200.

The controller interface circuit 212 may transmit data (e.g., user data) to be written in the non-volatile memory devices 300_1, 300_2, and 300_3 to the non-volatile memory devices 300_1, 300_2, and 300_3, or receive data (e.g., user data) read from the non-volatile memory devices 300_1, 300_2, and 300_3. The controller interface circuit 212 may be implemented to comply with a standard protocol such as toggle or ONFI (Open NAND Flash Interface).

In some example embodiments, the index read unit 214 may efficiently read data corresponding to a mapping table (or index) from the non-volatile memory devices 300_1, 300_2, and 300_3, and deliver it to the CPU 213 or a DMA engine, etc.

The flash translation layer 215 may perform several functions such as address mapping, wear-leveling, and garbage collection. Further, the buffer memory 216 may temporarily store data to be written in the memory device 300 and/or data read from the non-volatile memory devices 300_1, 300_2, and 300_3. The buffer memory 216 may be included in the storage controller 200, but may be located outside the storage controller 200.

The ECC engine 217 may perform error detection and correction on read data read from the non-volatile memory devices 300_1, 300_2, and 300_3. More specifically, the ECC engine 217 may generate parity bits for write data to be written to the non-volatile memory devices 300_1, 300_2, and 300_3, and the generated parity bits may be stored together with the write data in the non-volatile memory devices 300_1, 300_2, and 300_3. When data is read from the non-volatile memory devices 300_1, 300_2, and 300_3, the ECC engine 217 may correct errors in the read data using the parity bits read from the non-volatile memory devices 300_1, 300_2, and 300_3 together with the read data, and output the error-corrected read data.

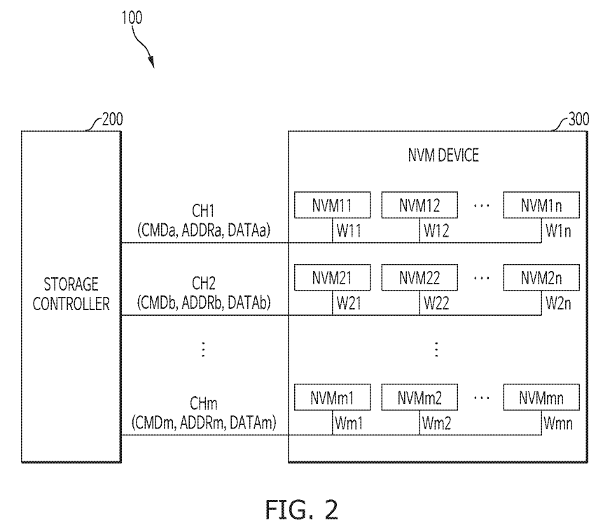

FIG. 2 illustrates a block diagram of a storage device according to some embodiments of the present disclosure.

Referring to FIG. 2, a memory device 300 and a storage controller 200 may be connected via multiple channels CH1 to CHm.

The memory device 300 may include a plurality of non-volatile memory devices NVM11 to NVMmn, where m and n may be natural numbers. The plurality of non-volatile memory devices NVM11 to NVMmn may correspond to the plurality of non-volatile memory devices 300_1, 300_2, and 300_3 of FIG. 1.

Each of the non-volatile memory devices NVM11 to NVMmn may be connected to one of the multiple channels CH1 to CHm via respective ways W11 to Wmn, thereby being connected to the storage controller 200. In some embodiments, each of the non-volatile memory devices NVM11 to NVMmn may be implemented as any memory unit capable of operating according to an individual command from the storage controller 200. For example, each of the non-volatile memory devices NVM11 to NVMmn may be implemented as a chip or a die, but the present disclosure is not limited thereto.

The storage controller 200 may transmit and receive data signals to and from the memory device 300 through the multiple channels CH1 to CHm. For example, the storage controller 200 may transmit commands CMDa to CMDm, addresses ADDRa to ADDRm, and data DATAa to DATAm to the memory device 300 through the channels CH1 to CHm, or receive data DATAa to DATAm from the memory device 300.

The storage controller 200 may select one of the non-volatile memory devices in the memory device 300 connected to each channel, and transmit and receive signals to and from the selected non-volatile memory device. In an example, each of the channels CH1 to CHm may include a command/address line and multiple data lines, described later, and multiple non-volatile memory devices may be selectively connected to one channel so as to communicate with the storage controller 200.

The storage controller 200 may transmit and receive signals to and from the memory device 300 in parallel via different channels. For example, the storage controller 200 may transmit a command CMDa to the memory device NVM11 through a first channel CH1 while transmitting a command CMDb to the memory device NVM21 through a second channel CH2. As another example, the storage controller 200 may receive data DATAa from the memory device NVM11 through the first channel CH1 while receiving data DATAb from the memory device NVM21 through the second channel CH2.

In FIG. 2, the memory device 300 is shown as communicating with the storage controller 200 through m channels, and including n non-volatile memory devices corresponding to each channel, but the number of channels and the number of non-volatile memory devices connected to one channel may be variously modified.

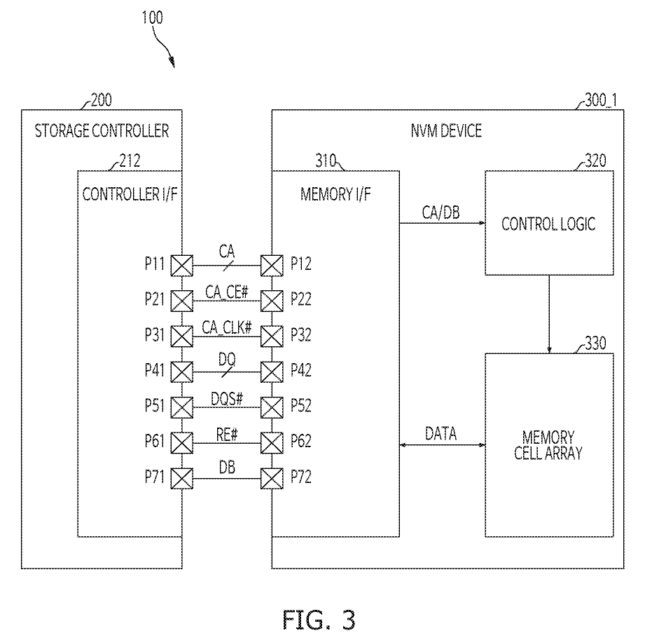

FIGS. 3 through 19 and various embodiments of the present disclosure described below with reference thereto illustrate and describe, by way of example, an operation of one of the plurality of non-volatile memory devices NVM11 to NVMmn, namely the non-volatile memory device 300_1. However, it is merely for convenience of description and is not limited thereto.

FIG. 3 illustrates a block diagram of a storage device according to some embodiments of the present disclosure. The non-volatile memory device 300_1 of FIG. 3 may correspond to any one of the non-volatile memory devices NVM11 to NVMmn (where m and n are natural numbers) described with reference to FIG. 2. In an example, the storage controller 200 and the non-volatile memory device 300_1 may communicate using an SCA (separate command address) protocol. However, it is not limited thereto.

Referring to FIG. 3, the storage controller 200 and the non-volatile memory device 300_1 may transmit and receive signals through multiple lines connected to multiple pins.

In some embodiments, the storage controller 200 may include a controller interface circuit 212. The controller interface circuit 212 may include pins P11, P21, P31, P41, P51, P61, and P71.

In some embodiments, the non-volatile memory device 300_1 may include a memory interface circuit 310, control logic 320, and a memory cell array 330. The memory interface circuit 310 may include pins P12, P22, P32, P42, P52, P62, and P72.

The pins P11 to P71 of the storage controller 200 may correspond to the pins P12 to P72 of the non-volatile memory device 300_1.

A command/address line CA may be connected to pins P11 and P12. Through pin P11, the controller interface circuit 212 may transmit command/address signals to the non-volatile memory device 300_1, and through pin P12, the memory interface circuit 310 may receive those signals. In some embodiments, the command/address signals may be transmitted through multiple pins. For example, pin P11 of the controller interface circuit 212 may include multiple pins (e.g., two pins), and pin P12 of the memory interface circuit 310 may include multiple pins (e.g., two pins) connected to pin P11 of the controller interface circuit 212.

In the present specification, pin P11 of the controller interface circuit 212 and pin P12 of the memory interface circuit 310 may each be referred to as a “command/address (CA) pin” or a “CA pin.” Further, in the present specification, the line connecting pin P11 of the controller interface circuit 212 and pin P12 of the memory interface circuit 310—that is, the line over which commands/addresses are transmitted to the memory interface circuit 310—may be referred to as a “command/address line” or “CA line.”

A command/address chip enable line CA_CE# may be connected to pins P21 and P22. Through pin P21, the controller interface circuit 212 may transmit a chip enable signal to the non-volatile memory device 300_1, and through pin P22, the memory interface circuit 310 may receive that signal. The chip enable signal may be a signal for selecting the non-volatile memory device that will receive command/address signals through the command/address line CA.

A command/address clock line CA_CLK# may be connected to pins P31 and P32. Through pin P31, the controller interface circuit 212 may transmit a command/address clock signal to the non-volatile memory device 300_1, and through pin P32, the memory interface circuit 310 may receive that signal. The command/address clock signal may toggle when command/address signals are provided to the non-volatile memory device 300_1 through the command/address line CA. In some embodiments, the non-volatile memory device 300_1 may receive command/address signals from the storage controller 200 in response to both the rising and falling edges of the command/address clock signal.

A data line DQ may be connected to pins P41 and P42. Through pin P41, the controller interface circuit 212 may transmit data to the non-volatile memory device 300_1, and through pin P42, the memory interface circuit 310 may receive that data. Also, through pin P42, the memory interface circuit 310 may transmit data to the storage controller 200, and through pin P41, the controller interface circuit 212 may receive that data. In some embodiments, data may be transmitted through multiple pins. For example, pin P41 of the controller interface circuit 212 may include multiple pins (e.g., eight pins), and pin P42 of the memory interface circuit 310 may include multiple pins (e.g., eight pins) connected to pin P41 of the controller interface circuit 212.

In the present specification, pin P41 of the controller interface circuit 212 and pin P42 of the memory interface circuit 310 may each be referred to as a “data pin” or a “DQ pin.” Further, in the present specification, the line connecting pin P41 of the controller interface circuit 212 and pin P42 of the memory interface circuit 310—that is, the line over which data is transmitted between the controller interface circuit 212 and the memory interface circuit 310—may be referred to as a “data line” or a “DQ line.”

A data strobe line DQS# may be connected to pins P51 and P52. Through pin P51, the controller interface circuit 212 may transmit a data strobe signal to the non-volatile memory device 300_1, and through pin P52, the memory interface circuit 310 may receive that signal. The data strobe signal may toggle when data is provided from the storage controller 200 to the non-volatile memory device 300_1 via the data line DQ. Also, the data strobe signal may toggle when data is provided from the non-volatile memory device 300_1 to the storage controller 200 via the data line DQ. The storage controller 200 or the non-volatile memory device 300_1 may receive data in response to both the rising and falling edges of the data strobe signal.

A read enable line RE# may be connected to pins P61 and P62. Through pin P61, the controller interface circuit 212 may transmit a read enable signal to the non-volatile memory device 300_1, and through pin P62, the memory interface circuit 310 may receive that signal. The read enable signal may toggle when data is provided from the non-volatile memory device 300_1 to the storage controller 200 via the data line.

A data burst line DB may be connected to pins P71 and P72. Through pin P71, the controller interface circuit 212 may transmit a data burst signal to the non-volatile memory device 300_1, and through pin P72, the memory interface circuit 310 may receive that signal. In some embodiments, the data burst signal may include a data burst enable signal and a data burst disable signal. The memory interface circuit 310 may receive a data burst enable signal (e.g., a high level) when the data burst signal is in an enable state, and may receive a data burst disable signal (e.g., a low level) when the data burst signal is in a disable state. However, the present disclosure is not limited thereto, and the definitions of enable/disable signals may vary depending on the embodiments.

In the present specification, pin P71 of the controller interface circuit 212 and pin P72 of the memory interface circuit 310 may each be referred to as a “data burst (DB) pin,” and the line connecting pin P71 of the controller interface circuit 212 and pin P72 of the memory interface circuit 310—that is, the line over which the data burst signal is transmitted to the memory interface circuit 310—may be referred to as a “data burst line” or “DB line.”

The control logic 320 may generally control various operations of the non-volatile memory device 300_1. The control logic 320 may receive commands/addresses acquired from the memory interface circuit 310. The control logic 320 may generate control signals to control other components of the non-volatile memory device 300_1, based on the received commands/addresses. For example, the control logic 320 may generate various control signals for programming data DATA into the memory cell array 330 or reading data DATA from the memory cell array 330. As another example, the control logic 320 may generate control signals to perform an ODT activation operation.

In some embodiments, the control logic 320 may perform different subsequent operations depending on whether the received command is a command assigned to that non-volatile memory device 300_1. For example, if the control logic 320 determines that the received command is assigned to that non-volatile memory device 300_1, it may generate control signals to perform a memory access operation, and if not, it may generate control signals to perform an on-die termination (ODT) activation operation. To this end, the control logic 320 may determine whether the command is assigned to itself, based on address or identifier information associated with the command.

Additionally or alternatively, the control logic 320 may be configured to perform a memory access operation only when a chip enable signal is received. For example, when the non-volatile memory device 300_1 receives a chip enable signal, it may generate control signals to perform a memory access operation based on a data burst enable signal, and otherwise may generate control signals to perform an ODT activation operation.

Here, the memory access operation may include a read operation or a write operation. In the case of a read operation, the non-volatile memory device 300_1 may activate a transmitter to output data. In the case of a write operation, the non-volatile memory device 300_1 may activate a receiver to input data.

The memory cell array 330 may store data DATA acquired from the memory interface circuit 310 under the control of the control logic 320. Also, under the control of the control logic 320, the memory cell array 330 may output stored data DATA to the memory interface circuit 310.

The memory cell array 330 may include a plurality of memory cells. For example, the plurality of memory cells may be flash memory cells. However, the present disclosure is not limited thereto, and the memory cells may be resistive random access memory (RRAM) cells, ferroelectric random access memory (FRAM) cells, phase change random access memory (PRAM) cells, thyristor random access memory (TRAM) cells, magnetic random access memory (MRAM) cells, etc.

The controller interface circuit 212 and the memory interface circuit 310 shown and described with reference to FIG. 3 are merely examples and are not limited thereto. For example, the controller interface circuit 212 and the memory interface circuit 310 may include additional pins for transmitting and receiving signals different from those shown and described with reference to FIG. 3. In another example, some of the pins P11 to P72 of the controller interface circuit 212 and the memory interface circuit 310 may be omitted or integrated with other pins.

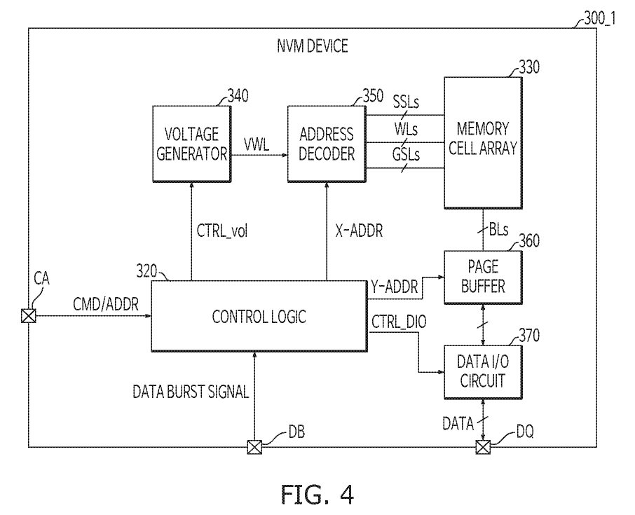

FIG. 4 illustrates a block diagram of a non-volatile memory device according to some embodiments of the present disclosure.

Referring to FIG. 4, the non-volatile memory device 300_1 may include control logic 320, a memory cell array 330, a voltage generator 340, an address decoder 350, a page buffer circuit 360, and a data input/output circuit 370. However, this is merely an example configuration for ease of description, and the non-volatile memory device 300_1 may further include additional components (for instance, the memory interface circuit 310 described with reference to FIG. 3).

The control logic 320 may generally control various operations in the non-volatile memory device 300_1. The control logic 320 may output various control signals in response to a command CMD and/or an address ADDR from the memory interface circuit 310. For example, the control logic 320 may output a voltage control signal CTRL_vol, a row address X-ADDR, a column address Y-ADDR, and an input/output circuit control signal CTRL_DIO.

In some embodiments, the control logic 320 may receive a command CMD and/or an address ADDR through the CA pin, and may receive a data burst signal through the DB pin. The data burst signal may include a data burst enable signal and a data burst disable signal. The control logic 320 may output the input/output circuit control signal CTRL_DIO to control the data input/output circuit 370 based on the data burst enable signal and/or the data burst disable signal.

The memory cell array 330 may be connected with the address decoder 350 through a plurality of string select lines SSLs, word lines WLs, and ground select lines GSLs. Also, the memory cell array 330 may be connected with the page buffer circuit 360 through a plurality of bit lines BLs. The memory cell array 330 may include multiple non-volatile memory cells connected to the plurality of word lines WLs and the plurality of bit lines BLs.

In some embodiments, the memory cell array 330 may include a three-dimensional memory cell array, which may include a plurality of NAND strings. Each NAND string may include memory cells connected respectively to word lines stacked vertically on a substrate. In some embodiments, the memory cell array 330 may include a two-dimensional memory cell array, which may include a plurality of NAND strings arranged along row and column directions.

The voltage generator 340 may generate various voltages for performing program, read, and erase operations, based on the voltage control signal CTRL_vol. For example, the voltage generator 340 may generate a program voltage, a read voltage, a program verify voltage, and an erase voltage, each serving as a word line voltage VWL.

The address decoder 350 may select one of the multiple word lines WL and one of the multiple string select lines SSL in response to the row address X-ADDR. For example, during a program operation, the address decoder 350 may apply a program voltage and/or a program verify voltage to the selected word line, and during a read operation, it may apply a read voltage to the selected word line.

The page buffer circuit 360 may be connected respectively to the memory cells through the plurality of bit lines BL. The page buffer circuit 360 may select at least one bit line among the bit lines BL in response to the column address Y-ADDR. The page buffer circuit 360 may operate as a write driver or a sense amplifier according to the operation mode. For example, during a program operation, the page buffer circuit 360 may apply a bit line voltage corresponding to the data to be programmed to the selected bit line. During a read operation, the page buffer circuit 360 may sense current or voltage on the selected bit line to detect the data stored in a memory cell.

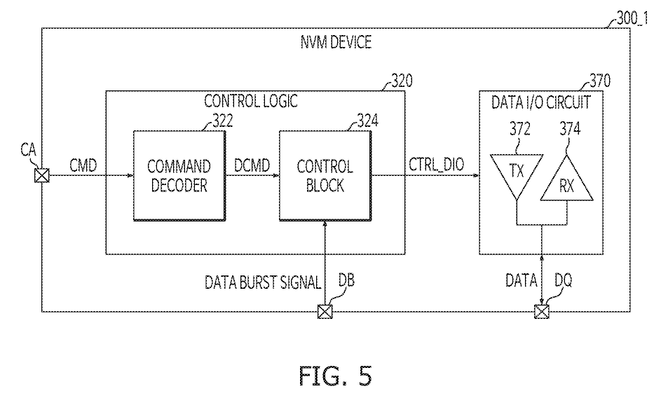

FIG. 5 is a diagram illustrating a non-volatile memory device according to some embodiments of the present disclosure.

Referring to FIG. 5, the non-volatile memory device 300_1 may include control logic 320 and a data input/output circuit 370. The control logic 320 may include a command decoder 322, which is connected to the CA pin, and a control block 324, which is connected to the data burst pin DB. The data input/output circuit 370 may include a transmitter 372 and a receiver 374, each connected to the data pin DQ and configured to transmit/receive data to/from the storage controller. However, this is merely an example configuration for convenience of description, and the non-volatile memory device 300_1 may further include additional components.

The command decoder 322 may receive a command CMD through the CA pin, and output a decoded command DCMD. The command decoder 322 may transmit the decoded command DCMD to the control block 324.

In some embodiments, the command decoder 322 may receive a memory access command from the storage controller through the CA pin while the storage controller is transmitting a first data burst enable signal through the data burst pin DB, decode the memory access command, and output at least one of a decoded data input command, a decoded data output command, or a decoded ODT command. For example, if the command decoder 322 decodes the memory access command and determines that the non-volatile memory device is a target non-volatile memory device that is configured to perform a write command, the command decoder 322 may output a decoded data input command. If the memory access command corresponds to a read command to be performed by a target non-volatile memory device, the command decoder 322 may output a decoded data output command. Also, if the memory access command corresponds to a non-target non-volatile memory device, the command decoder 322 may output a decoded ODT command.

The control block 324 may receive the data burst signal from the data burst pin DB and the decoded command DCMD from the command decoder 322, and may output an I/O circuit control signal CTRL_DIO. The control block 324 may transmit the I/O circuit control signal CTRL_DIO to the data input/output circuit 370.

In some embodiments, the control block 324 may receive and store the decoded command DCMD from the command decoder 322 while receiving the first data burst signal through the data burst pin DB. Subsequently, at the time the second data burst enable signal is received, the control block 324 may apply the decoded command and generate the I/O circuit control signal CTRL_DIO and transmit it to the data input/output circuit 370.

In some embodiments, when the control block 324 receives the decoded data input command, the control block 324 may control the receiver 374 to perform a write operation while receiving the second data burst enable signal. For example, to perform the write operation, the control block 324 may output a receiver control signal to activate the receiver 374.

In some embodiments, when the control block 324 receives the decoded data output command, the control block 324 may control the transmitter 372 to perform a read operation while receiving the second data burst enable signal. For example, to perform the read operation, the control block 324 may output a transmitter control signal CTRL_TX to activate the transmitter 372.

In some embodiments, when the control block 324 receives the decoded ODT command, the control block 324 may control the transmitter 372 to perform an ODT activation operation while receiving the second data burst enable signal. For example, to perform the ODT activation operation, the control block 324 may output an ODT control signal CTRL_ODT to control the transmitter 372 into an ODT activation state. Here, controlling the transmitter 372 into an ODT activation state may be for suppressing signal reflection and maintaining signal integrity by activating an internal termination resistor during a period when data is not being transmitted. This may enable stable data communication between the non-volatile memory device 300_1 and the storage controller.

In some embodiments, the control block 324 may receive a first data burst disable signal between the first data burst enable signal and the second data burst enable signal, and after receiving the second data burst enable signal, may receive a second data burst disable signal. When the second data burst disable signal is received, the control block 324 may generate the I/O circuit control signal CTRL_DIO corresponding to the operation performed while the second data burst enable signal was being received and transmit it to the data input/output circuit 370.

For example, if the control block 324 controlled the receiver 374 to perform a write operation while the second data burst enable signal was being received, the control block 324 may control the receiver 374 to end the write operation in response to receiving the second data burst disable signal. Also, if the control block 324 controlled the transmitter 372 to perform a read operation while the second data burst enable signal was being received, the control block 324 may control the transmitter 372 to end the read operation in response to receiving the second data burst disable signal. Further, if the control block 324 controlled the transmitter 372 to perform an ODT activation operation while the second data burst enable signal was being received, the control block 324 may control the transmitter 372 to end the ODT activation operation in response to receiving the second data burst disable signal.

Meanwhile, in FIG. 5, the control block 324 is shown as included within the control logic 320, but the scope of the present disclosure is not limited thereto. Thus, in some embodiments, the control block 324, which receives the decoded command DCMD from the command decoder 322 and outputs the I/O circuit control signal CTRL_DIO, may be implemented as a separate component from the control logic 320 and/or as a component included in the data input/output circuit 370.

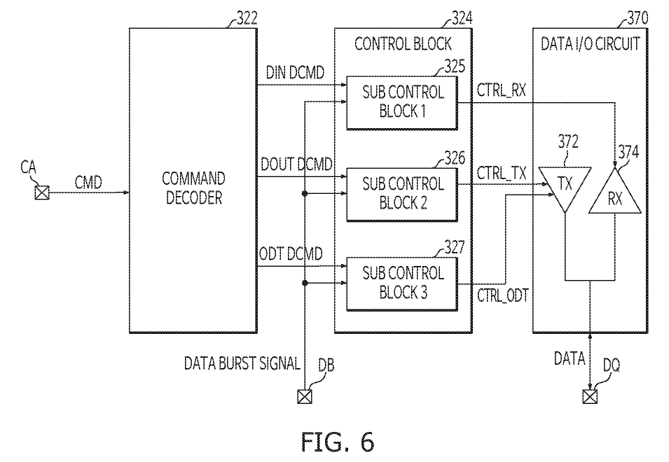

FIG. 6 is a diagram illustrating the configuration of a control block according to some embodiments of the present disclosure. Redundant descriptions are briefly stated or omitted.

Referring to FIG. 6, while the storage controller transmits a first data burst enable signal through the data burst pin DB, the command decoder 322 may receive a command CMD through the CA pin. The command decoder 322 may decode the received command CMD and output one of a decoded data input command DIN DCMD, a decoded data output command DOUT DCMD, or a decoded ODT command ODT DCMD to the control block 324.

In some embodiments, the control block 324 may include a first sub control block 325, a second sub control block 326, and a third sub control block 327.

The first sub control block 325 may receive the decoded data input command DIN DCMD from the command decoder 322, and may also receive the data burst signal from the data burst pin DB. Based on the decoded data input command DIN DCMD and the data burst signal, the first sub control block 325 may output a receiver control signal CTRL_RX.

In some embodiments, the first sub control block 325 may receive the decoded data input command DIN DCMD from the command decoder 322 while the storage controller transmits the first data burst enable signal through the data burst pin DB. Then, while the second data burst enable signal is being received through the data burst pin DB, the first sub control block 325 may output the receiver control signal CTRL_RX so as to perform a write operation according to the received decoded data input command DIN DCMD. Also, if the first sub control block 325 has output the receiver control signal CTRL_RX to perform the write operation while the second data burst enable signal is being received, it may, at the time the second data burst disable signal is received, output the receiver control signal CTRL_RX to end the write operation. The first sub control block 325 may transmit the receiver control signal CTRL_RX to the receiver 374.

The second sub control block 326 may receive the decoded data output command DOUT DCMD from the command decoder 322, and may also receive the data burst signal from the data burst pin DB. Based on the decoded data output command DOUT DCMD and the data burst signal, the second sub control block 326 may output a transmitter control signal CTRL_TX.

In some embodiments, the second sub control block 326 may receive the decoded data output command DOUT DCMD from the command decoder 322 while the storage controller transmits the first data burst enable signal through the data burst pin DB. Then, while the second data burst enable signal is being received through the data burst pin DB, the second sub control block 326 may output the transmitter control signal CTRL_TX so as to perform a read operation according to the received decoded data output command DOUT DCMD. Also, if the second sub control block 326 has output the transmitter control signal CTRL_TX to perform the read operation while the second data burst enable signal is being received, it may, at the time the second data burst disable signal is received, output the transmitter control signal CTRL_TX to end the read operation. The second sub control block 326 may transmit the transmitter control signal CTRL_TX to the transmitter 372.

The third sub control block 327 may receive the decoded ODT command ODT DCMD from the command decoder 322, and may also receive the data burst signal from the data burst pin DB. Based on the decoded ODT command ODT DCMD and the data burst signal, the third sub control block 327 may output an ODT control signal CTRL_ODT.

In some embodiments, the third sub control block 327 may receive the decoded ODT command ODT DCMD from the command decoder 322 while the storage controller transmits the first data burst enable signal through the data burst pin DB. Then, while the second data burst enable signal is being received through the data burst pin DB, the third sub control block 327 may output the ODT control signal CTRL_ODT so as to perform an ODT activation operation according to the received decoded ODT command ODT DCMD. Also, if the third sub control block 327 has output the ODT control signal CTRL_ODT to perform the ODT activation operation while the second data burst enable signal is being received, it may, at the time the second data burst disable signal is received, output the ODT control signal CTRL_ODT to end the ODT activation operation. The third sub control block 327 may transmit the ODT control signal CTRL_ODT to the transmitter 372.

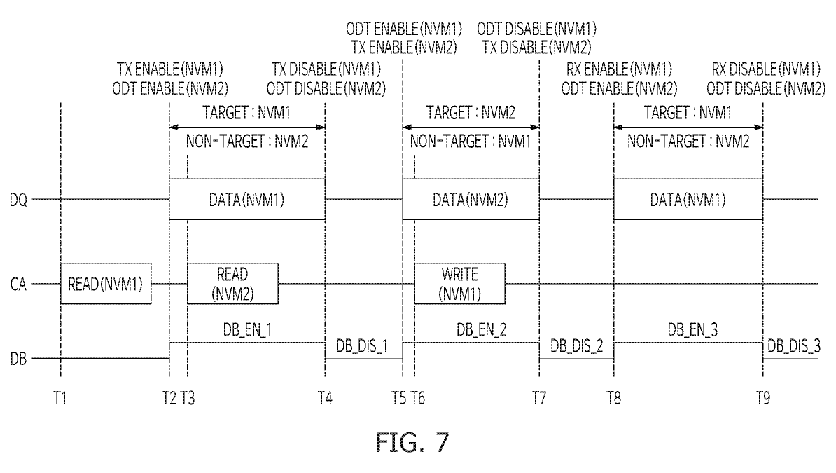

FIG. 7 is a diagram showing data transmission/reception processes and signal timings between a storage controller and a plurality of non-volatile memory devices according to some embodiments of the present disclosure.

In some embodiments, the storage controller may transmit commands to a plurality of non-volatile memory devices through the CA pin, and may transmit a data burst signal through the data burst pin DB. Also, the storage controller may transmit/receive data to/from the plurality of non-volatile memory devices through the data pin DQ. In FIG. 7, the plurality of non-volatile memory devices are described as including a first non-volatile memory device NVM1 and a second non-volatile memory device NVM2, but the present disclosure is not limited thereto.

Referring to FIG. 7, at time T1, the storage controller may transmit a read command READ(NVM1) associated with the first non-volatile memory device NVM1. In this case, the first non-volatile memory device NVM1 becomes a target non-volatile memory device, and the second non-volatile memory device NVM2 may operate as a non-target non-volatile memory device. Each non-volatile memory device may determine whether it is the target or non-target device based on address or identifier information associated with the command. In some examples, each non-volatile memory device may determine whether it is the target or non-target device based on a chip enable signal received via a command/address chip enable line. Also, in FIG. 7, it is shown that the read command READ(NVM1) associated with the first non-volatile memory device NVM1 is received while a data burst disable signal is being received, but the present disclosure is not limited thereto.

When a subsequent data burst enable signal is received (e.g., between time T2 and time T4), the target non-volatile memory device and the non-target non-volatile memory device may perform different operations. Specifically, the target non-volatile memory device may perform a memory access operation (e.g., data read or write), and the non-target non-volatile memory device may perform an ODT operation to suppress signal reflection.

Between time T2 and time T4, the storage controller may transmit a first data burst enable signal DB_EN_1 to the first non-volatile memory device NVM1 and the second non-volatile memory device NVM2. While receiving the first data burst enable signal DB_EN_1, the first non-volatile memory device NVM1, as the target non-volatile memory device, may control its transmitter in accordance with the read command and perform a memory access operation (read operation). While receiving the first data burst enable signal DB_EN_1, the second non-volatile memory device NVM2, as the non-target non-volatile memory device, may control its transmitter to perform an ODT activation operation.

At time T3, the storage controller may transmit a read command associated with the second non-volatile memory device NVM2. In this case, when a subsequent data burst enable signal is received (e.g., between time T5 and time T7), the second non-volatile memory device NVM2 becomes the target device, and the first non-volatile memory device NVM1 operates as a non-target device.

At time T4, the storage controller may transmit a first data burst disable signal DB_DIS_1 to the non-volatile memory devices NVM1 and NVM2. The first non-volatile memory device NVM1, as the target non-volatile memory device, may respond to receiving the first data burst disable signal DB_DIS_1 by controlling its transmitter to end the read operation. The second non-volatile memory device NVM2, as the non-target non-volatile memory device, may respond to receiving the first data burst disable signal DB_DIS_1 by controlling its transmitter to end the ODT activation operation.

Between time T5 and time T7, the storage controller may transmit a second data burst enable signal DB_EN_2 to the first non-volatile memory device NVM1 and the second non-volatile memory device NVM2. While receiving the second data burst enable signal DB_EN_2, the second non-volatile memory device NVM2, as the target device, may control its transmitter in accordance with the read command and perform a memory access operation (read operation). While receiving the second data burst enable signal DB_EN_2, the first non-volatile memory device NVM1, as the non-target device, may control its transmitter to perform an ODT activation operation.

At time T6, the storage controller may transmit a write command associated with the first non-volatile memory device NVM1. In this case, when a subsequent data burst enable signal is received (e.g., between time T8 and time T9), the first non-volatile memory device NVM1 becomes the target device, and the second non-volatile memory device NVM2 operates as a non-target device.

At time T7, the storage controller may transmit a second data burst disable signal DB_DIS_2 to the non-volatile memory devices NVM1 and NVM2. The second non-volatile memory device NVM2, as the target device, may respond to receiving the second data burst disable signal DB_DIS_2 by controlling its transmitter to end the read operation. The first non-volatile memory device NVM1, as the non-target device, may respond to receiving the second data burst disable signal DB_DIS_2 by controlling its transmitter to end the ODT activation operation.

Between time T8 and time T9, the storage controller may transmit a third data burst enable signal DB_EN_3 to the first non-volatile memory device NVM1 and the second non-volatile memory device NVM2. While receiving the third data burst enable signal DB_EN_3, the first non-volatile memory device NVM1, as the target device, may control its receiver in accordance with the write command and perform a memory access operation (write operation). While receiving the third data burst enable signal DB_EN_3, the second non-volatile memory device NVM2, as the non-target device, may control its transmitter to perform an ODT activation operation.

At time T9, the storage controller may transmit a third data burst disable signal DB_DIS_3 to the non-volatile memory devices NVM1 and NVM2. The first non-volatile memory device NVM1, as the target device, may respond to receiving the third data burst disable signal DB_DIS_3 by controlling its receiver to end the write operation. The second non-volatile memory device NVM2, as the non-target device, may respond to receiving the third data burst disable signal DB_DIS_3 by controlling its transmitter to end the ODT activation operation.

In some embodiments, while receiving a data burst disable signal, the first non-volatile memory device NVM1 and the second non-volatile memory device NVM2 may not receive (or refrain from receiving) one or more additional commands from the storage controller through the CA pin. For example, the first and second non-volatile memory devices NVM1 and NVM2 may not receive additional commands through the CA pin from the storage controller while receiving the first, second, and third data burst disable signals DB_DIS_1, DB_DIS_2, and DB_DIS_3. However, by exception, during an initial interval T1 to T2, a read and/or write command for a new data transfer may be transmitted. For example, during a system initialization process or when a new memory access request occurs, a command may be transmitted while a data burst disable signal is being transmitted. Through this configuration, unnecessary waiting time may be reduced during data transmission, improving overall data transmission efficiency.

In some embodiments, between intervals in which a memory access operation for data transmission is performed, the first non-volatile memory device NVM1 and the second non-volatile memory device NVM2 may not receive additional commands from the storage controller through the CA pin. The first non-volatile memory device NVM1 and the second non-volatile memory device NVM2 may not receive additional commands from the storage controller through the CA pin between the interval from time T2 to T4 and the interval from time T5 to T7, and/or between the interval from time T5 to T7 and the interval from time T8 to T9. That is, the first non-volatile memory device NVM1 and the second non-volatile memory device NVM2 may not receive additional commands in the interval from time T4 to T5 and/or from time T7 to T8. Through this configuration, the time interval between memory access operations may be shortened, and overall data transmission speed may be improved.

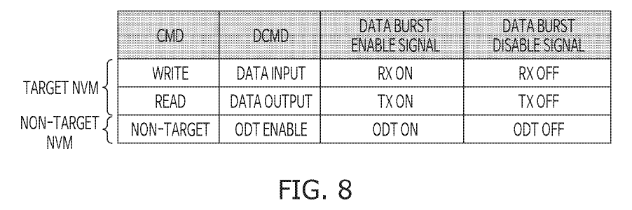

FIG. 8 is a diagram illustrating operations performed when a data burst enable signal and a data burst disable signal are received, according to commands and decoded commands received by a non-volatile memory device. The first row of FIG. 8 indicates commands and related signals received by the non-volatile memory device, and each column indicates operations of the non-volatile memory device according to those commands and signals.

Referring to the first column of FIG. 8, the non-volatile memory device may be classified as a target non-volatile memory device or a non-target non-volatile memory device according to the received command CMD. That is, based on address or identifier information associated with the command CMD, the non-volatile memory device may determine whether to operate as a target or non-target device. For example, a non-volatile memory device that has received a write or read command may operate as a target device, while a non-volatile memory device that has no data access request may perform an ODT (on-die termination) function as a non-target device.

Referring to the second column of FIG. 8, the decoded command DCMD may be output according to the received command CMD. For example, if a write command is received, it may be decoded into a data input command, and if a read command is received, it may be decoded into a data output command. Also, if the non-volatile memory device is a non-target device, it may be decoded into an ODT enable command.

Depending on the decoded command DCMD, the operation to be performed when the data burst enable signal and the data burst disable signal that are received may differ. Referring to the third column of FIG. 8, when the non-volatile memory device receives the data burst enable signal, the target non-volatile memory device may perform a memory access operation. For example, if the target non-volatile memory device has received a write command, it may activate its receiver (RX ON) to receive data. If the target non-volatile memory device has received a read command, it may activate its transmitter (TX ON) to output data. Meanwhile, the non-target non-volatile memory device may activate (ODT ON) its ODT function to suppress signal reflection while the data burst enable signal is being received.

Referring to the fourth column of FIG. 8, when the non-volatile memory device receives the data burst disable signal, it may end the operation previously being performed. For example, upon receiving the data burst disable signal, if the target non-volatile memory device was performing a write command, it may deactivate its receiver (RX OFF), and if it was performing a read command, it may deactivate its transmitter (TX OFF). Also, the non-target non-volatile memory device may deactivate its ODT function (ODT OFF) when it receives the data burst disable signal.

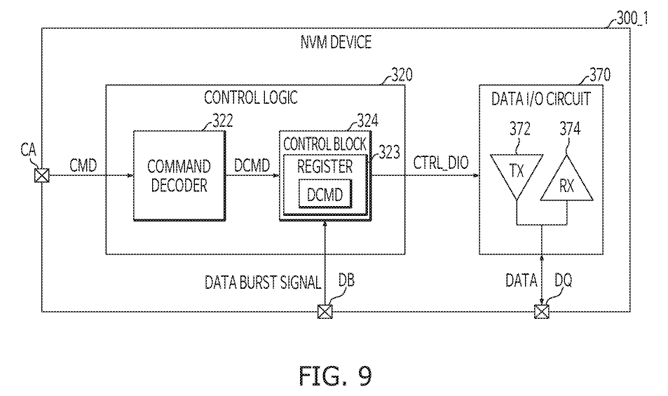

FIG. 9 is a diagram illustrating a non-volatile memory device according to some embodiments of the present disclosure. Redundant descriptions overlapping with those explained with reference to FIG. 5 are omitted or briefly stated.

Referring to FIG. 9, the control block 324 may include a register 323 that temporarily stores the decoded command DCMD. That is, the control block 324 may receive the decoded command DCMD from the command decoder 322 and store it in the register 323.

In some embodiments, when the first data burst enable signal is received, the control block 324 may temporarily store the decoded command in the register 323. Then, when the second data burst enable signal is received, the control block 324 may perform a subsequent operation based on the decoded command DCMD stored in the register 323. By doing so, the processing time of the decoded command DCMD may be adjusted, and the data burst signal may be used to control the start and end timings of the memory access operation and/or the ODT activation operation.

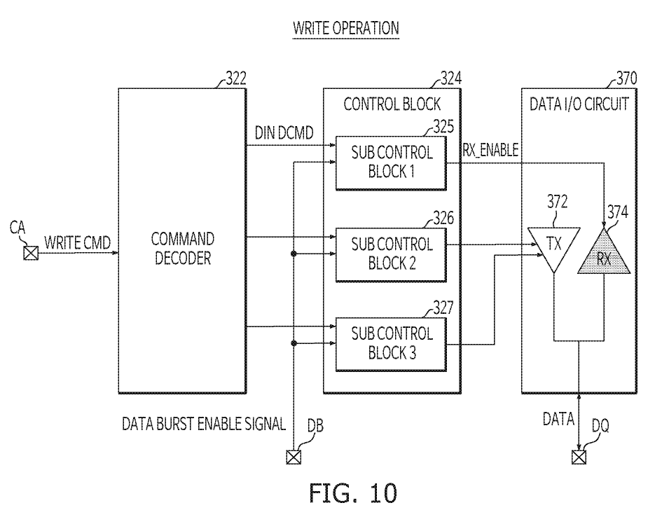

FIG. 10 is a diagram illustrating a signal flow when a write command is received, according to some embodiments of the present disclosure. Redundant descriptions overlapping with the above description are omitted or briefly stated.

Referring to FIG. 10, a write command WRITE CMD may be delivered to the command decoder 322 through the CA pin, and the command decoder 322 may decode it into a decoded data input command DIN DCMD. This process may be performed while the storage controller is transmitting the first data burst enable signal.

The decoded data input command DIN DCMD may be provided to the first sub control block 325 in the control block 324. While the second data burst enable signal is being received, the first sub control block 325 may output a receiver enable signal RX_ENABLE to control the receiver 374 so as to perform the write operation. Also, while the second data burst enable signal is maintained, the memory access operation may be performed through the receiver 374.

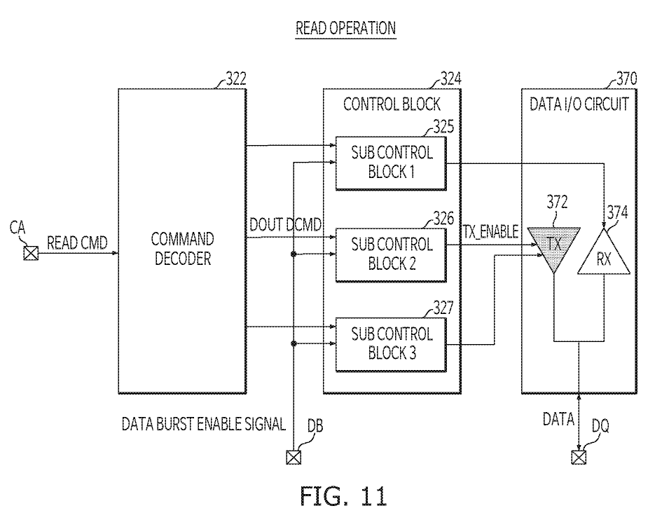

FIG. 11 is a diagram illustrating a signal flow when a read command is received, according to some embodiments of the present disclosure. Redundant descriptions overlapping with the above description are omitted or briefly stated.

Referring to FIG. 11, a read command READ CMD may be delivered to the command decoder 322 through the CA pin, and the command decoder 322 may decode it into a decoded data output command DOUT DCMD. This process may be performed while the storage controller is transmitting the first data burst enable signal DB_EN_1.

The decoded data output command DOUT DCMD may be provided to the second sub control block 326 in the control block 324. While the second data burst enable signal is being received, the second sub control block 326 may output a transmitter enable signal TX_ENABLE to control the transmitter 372 so as to perform the read operation. Also, while the second data burst enable signal is maintained, the memory access operation may be performed through the transmitter 372.

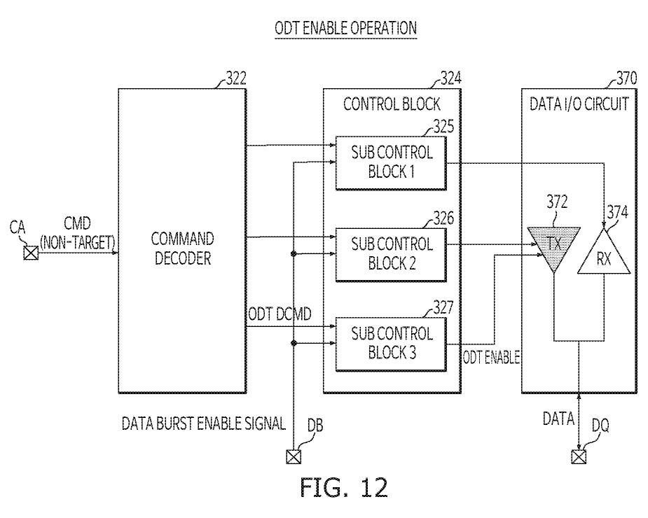

FIG. 12 is a diagram illustrating a signal flow during an ODT activation operation according to some embodiments of the present disclosure. Redundant descriptions overlapping with the above description are omitted or briefly stated.

Referring to FIG. 12, a command CMD may be delivered to the command decoder 322 through the CA pin, and the command decoder 322 may decode it into a decoded ODT command ODT DCMD. In this process, the command decoder 322 may refer to address information or other associated information included in the command, determine that the command is not assigned to itself, and accordingly output the decoded ODT command ODT DCMD. This process may be performed while the storage controller is transmitting the first data burst enable signal.

The decoded ODT command ODT DCMD may be provided to the third sub control block 327 in the control block 324. While the second data burst enable signal is being received, the third sub control block 327 may output an ODT enable signal ODT ENABLE to perform the ODT activation operation by controlling the transmitter 372. Also, while the second data burst enable signal is maintained, the non-volatile memory device operating as a non-target device may perform the ODT activation operation by controlling the transmitter 372.

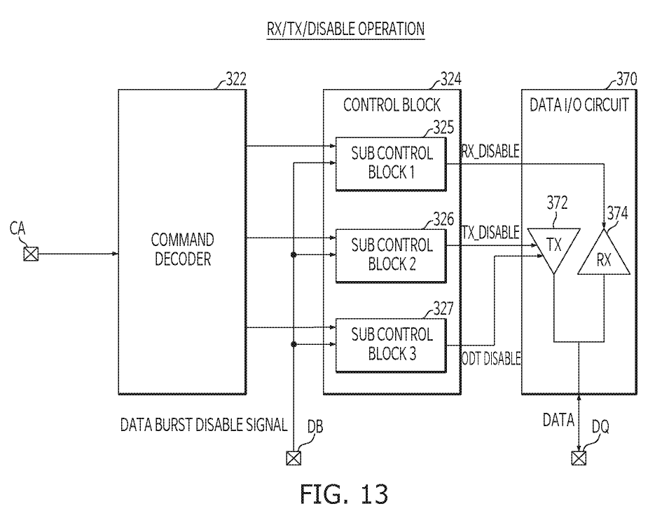

FIG. 13 is a diagram illustrating an operation performed when a data burst disable signal is received, according to some embodiments of the present disclosure. Redundant descriptions overlapping with the above description are omitted or briefly stated.

Referring to FIG. 13, at the time the data burst disable signal is received, the sub control blocks 325, 326, and 327 in the control block 324 may output a receiver disable signal RX_DISABLE, a transmitter disable signal TX_DISABLE, and an ODT disable signal ODT_DISABLE, respectively.

In some embodiments, when the second data burst disable signal is received, the first sub control block 325 may output the receiver disable signal RX_DISABLE, and control the receiver 374 to end the write operation that was performed while the second data burst enable signal was being received. When the second data burst disable signal is received, the second sub control block 326 may output the transmitter disable signal TX_DISABLE, and control the transmitter 372 to end the read operation that was performed while the second data burst enable signal was being received. When the second data burst disable signal is received, the third sub control block 327 may output the ODT disable signal ODT_DISABLE, and control the transmitter 372 to end the ODT activation operation that was performed while the second data burst enable signal was being received.

In FIG. 13, the sub control blocks 325, 326, and 327 in the control block 324 are all shown outputting the signals RX_DISABLE, TX_DISABLE, and ODT_DISABLE simultaneously for convenience of description. However, this is for explanatory purposes. In another example, based on the preceding operation (e.g., write operation, read operation, or ODT activation operation), the control block 324 may output only one of the receiver disable signal RX_DISABLE, the transmitter disable signal TX_DISABLE, or the ODT disable signal ODT_DISABLE when the data burst disable signal is received.

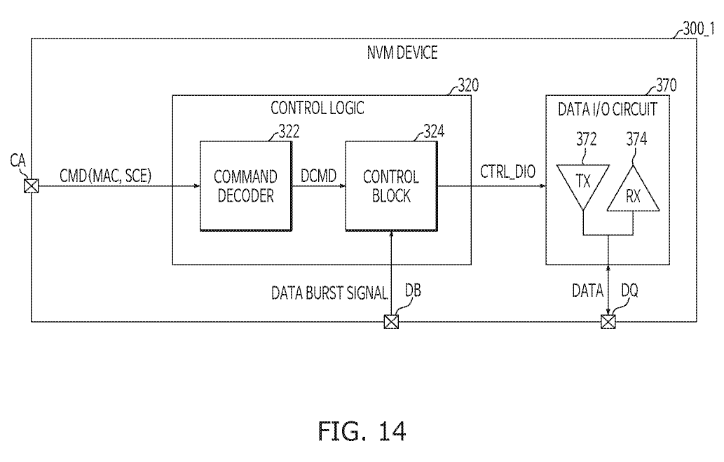

FIG. 14 is a diagram illustrating a non-volatile memory device according to some embodiments of the present disclosure. Redundant descriptions overlapping with those explained with reference to FIG. 5 are omitted or briefly stated.

In some embodiments, a target non-volatile memory device may receive a memory access command (MAC) and a select chip enable (SCE) command while receiving a first data burst enable signal. Subsequently, at the time a second data burst enable signal is received, the target non-volatile memory device may perform a target chip activation operation based on the SCE command. At the time a second data burst disable signal is received, the target non-volatile memory device may end the memory access operation. Here, the target chip activation operation may include activating a transmitter and/or receiver to perform the memory access operation.

In some embodiments, a non-target non-volatile memory device may determine whether it has received the SCE command while receiving the first data burst enable signal. In response to determining that the SCE command has not been received, the non-target non-volatile memory device may perform an ODT activation operation at the time the second data burst enable signal is received. Also, the non-target non-volatile memory device may end the ODT activation operation at the time the second data burst disable signal is received.

In some embodiments, the non-target non-volatile memory device may perform or end the ODT activation operation based on address or identifier information included in the memory access command (MAC), without determining whether the select chip enable SCE command is received.

Additionally or alternatively, the non-target non-volatile memory device may receive the select chip enable SCE command and, based on address or identifier information included therein, perform or end the ODT activation operation.

Referring to FIG. 14, the command decoder 322 may receive the memory access command MAC and the select chip enable SCE command through the CA pin, and may output a decoded command DCMD based on the received memory access command MAC and select chip enable SCE command.

In some embodiments, if both a write command and an SCE command are received, the command decoder 322 may output a decoded data input command DIN DCMD. On the other hand, if both a read command and an SCE command are received, the command decoder 322 may output a decoded data output command DOUT DCMD. Also, if only the MAC is received or if both the MAC and the SCE command are received but the address or identifier associated with the command does not correspond to the non-volatile memory device, the command decoder 322 may output a decoded ODT command ODT DCMD. Through this, each non-volatile memory device may perform an appropriate operation as a target or non-target non-volatile memory device.

The command and/or signal output from the command decoder 322 may be transferred to the control block 324. The control block 324 may output an I/O circuit control signal CTRL_DIO based on the received command and/or signal and the data burst signal.

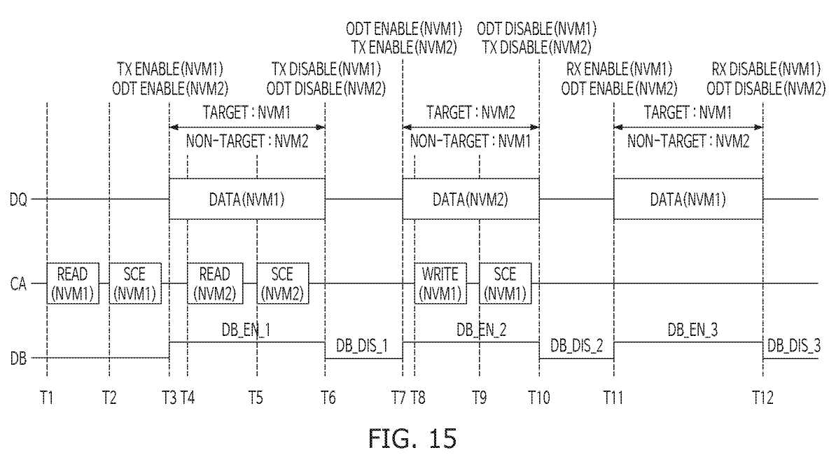

FIG. 15 is a diagram illustrating data transmission/reception processes and signal timings between a storage controller and a plurality of non-volatile memory devices according to some embodiments of the present disclosure. Redundant descriptions overlapping with those explained with reference to FIG. 7 are omitted or briefly stated.

Referring to FIG. 15, the storage controller may further transmit a select chip enable command SCE to the plurality of non-volatile memory devices through the CA pin. The SCE command may serve to set a specific non-volatile memory device as a target device together with a memory access command MAC.

Referring to FIG. 15, at time T1, the storage controller may transmit a read command READ(NVM1) associated with the first non-volatile memory device NVM1, and at time T2, it may transmit an SCE command associated with the first non-volatile memory device NVM1. Through this, the first non-volatile memory device NVM1 may be set as the target device, and the second non-volatile memory device NVM2 may operate as a non-target device.

Between time T3 and time T6, the storage controller may transmit a first data burst enable signal DB_EN_1 to the first non-volatile memory device NVM1 and the second non-volatile memory device NVM2. While receiving DB_EN_1, the first non-volatile memory device NVM1, as the target device, may perform a read operation in accordance with the read command and the SCE command, and the second non-volatile memory device NVM2, as the non-target device, may perform an ODT activation operation.

At time T4, the storage controller may transmit a read command associated with the second non-volatile memory device NVM2, and at time T5, the storage controller may transmit an SCE command associated with the second non-volatile memory device NVM2.

At time T6, the storage controller may transmit a first data burst disable signal DB_DIS_1 to the first non-volatile memory device NVM1 and the second non-volatile memory device NVM2. At the time DB_DIS_1 is received, the first non-volatile memory device NVM1 may end the memory access operation, and the second non-volatile memory device NVM2 may end the ODT activation operation.

Between time T7 and time T10, the storage controller may transmit a second data burst enable signal DB_EN_2. While receiving DB_EN_2, a memory access operation or an ODT activation operation may be performed.

At time T8, the storage controller may transmit a write command associated with the first non-volatile memory device NVM1, and at time T9, the storage controller may transmit an SCE command associated with the first non-volatile memory device NVM1.

At time T10, the storage controller may transmit a second data burst disable signal DB_DIS_2. At the time DB_DIS_2 is received, the second non-volatile memory device NVM2 may end the memory access operation, and the first non-volatile memory device NVM1 may end the ODT activation operation.

Between time T11 and time T12, the first non-volatile memory device NVM1 may perform the memory access operation, and the second non-volatile memory device NVM2 may perform the ODT activation operation. Further, at time T12, the first non-volatile memory device NVM1 may end the memory access operation, and the second non-volatile memory device NVM2 may end the ODT activation operation.

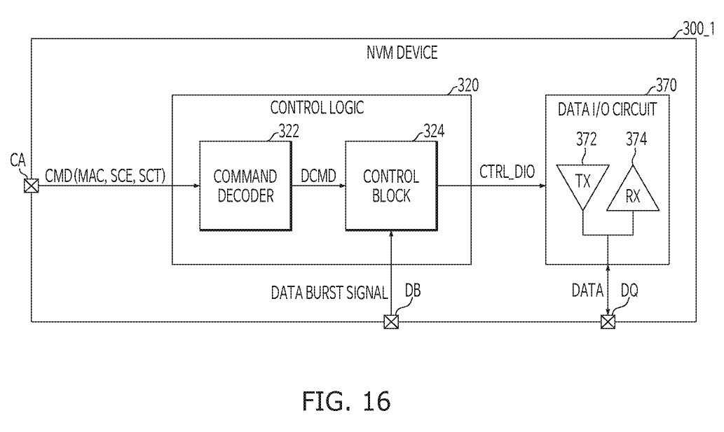

FIG. 16 is a diagram illustrating a non-volatile memory device according to some embodiments of the present disclosure. Redundant descriptions overlapping with those explained with reference to FIGS. 5 and 14 are omitted or briefly stated.

In some embodiments, a target non-volatile memory device may receive an SCE command while receiving a first data burst enable signal DB_EN_1, and receive a select chip termination (SCT) command while receiving a second data burst enable signal DB_EN_2. Subsequently, at the time the second data burst enable signal DB_EN_2 is received, the target non-volatile memory device may perform a target chip activation operation based on the SCE command, and at the time the second data burst disable signal DB_DIS_2 is received, may perform a target chip termination operation based on the SCT command. Here, the target chip activation operation may include activating a transmitter and/or a receiver to perform the memory access operation, and the target chip termination operation may include deactivating the transmitter and/or the receiver to end the memory access operation.

In some embodiments, a non-target non-volatile memory device may perform an ODT activation operation at the time the second data burst enable signal DB_EN_2 is received, based on the SCE command. Also, while receiving the second data burst enable signal DB_EN_2, the non-target non-volatile memory device may determine whether the SCT command is received, and if it determines that the SCT command is not received, may end the ODT activation operation at the time the second data burst disable signal DB_DIS_2 is received.

In some embodiments, the non-target non-volatile memory device may perform or end the ODT activation operation based on an address or identifier information included in the memory access command MAC, without determining whether the SCE or SCT command is received.

Additionally or alternatively, the non-target non-volatile memory device may receive the SCE command or the SCT command and, based on address or identifier information included therein, perform or end the ODT activation operation.

Referring to FIG. 16, the command decoder 322 may receive the memory access command MAC, the SCE command, and the SCT command through the CA pin, and may output a decoded command DCMD based on the MAC, SCE command, and SCT command.

In some embodiments, if the command decoder 322 receives a write command and the SCE command, it may output a decoded data input command DIN DCMD. Subsequently, if the command decoder 322 receives the SCT command, it may output a decoded data input termination command. Also, if the command decoder 322 receives a read command and the SCE command, the command decoder 322 may output a decoded data output command DOUT DCMD. If the command decoder 322 receives the SCT command, the command decoder 322 may output a decoded data output termination command.

The command output from the command decoder 322 may be transmitted to the control block 324. The control block 324 may output an I/O circuit control signal CTRL_DIO based on the received decoded command DCMD and the data burst signal.

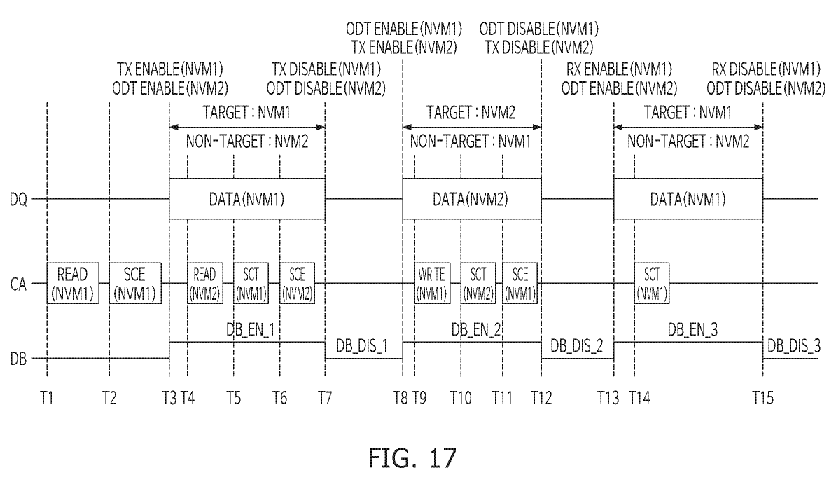

FIG. 17 is a diagram illustrating data transmission/reception processes and signal timings between a storage controller and a plurality of non-volatile memory devices according to some embodiments of the present disclosure. Redundant descriptions overlapping with those explained with reference to FIGS. 7 and 15 are omitted or briefly stated.

Referring to FIG. 17, the storage controller may further transmit a select chip termination command SCT to the plurality of non-volatile memory devices through the CA pin. The SCT command may serve to set a non-volatile memory device(s) that will end the memory access operation.

Referring to FIG. 17, at time T1, the storage controller may transmit a read command associated with the first non-volatile memory device NVM1, and at time T2, the storage controller may transmit an SCE command associated with the first non-volatile memory device NVM1.

Between time T3 and time T7, the storage controller may transmit a first data burst enable signal DB_EN_1. While receiving DB_EN_1, the first non-volatile memory device NVM1 may perform a read operation in accordance with the SCE command and the read command, and the second non-volatile memory device NVM2 may perform an ODT activation operation. 1

At time T4, the storage controller may transmit a read command associated with the second non-volatile memory device NVM2, at time T5, the storage controller may transmit an SCT command associated with the first non-volatile memory device NVM1, and at time T6, the storage controller may transmit an SCE command associated with the second non-volatile memory device NVM2.

At time T7, when the first data burst disable signal DB_DIS_1 is received, the first non-volatile memory device NVM1 may end the memory access operation based on the SCT command associated with the first non-volatile memory device NVM1, and the second non-volatile memory device NVM2 may end the ODT activation operation.

Between time T8 and time T12, while the second data burst enable signal DB_EN_2 is being received, a memory access operation or an ODT activation operation may be performed.

At time T9, the storage controller may transmit a write command associated with the first non-volatile memory device NVM1, at time T10, the storage controller may transmit an SCT command associated with the second non-volatile memory device NVM2, and at time T11, the storage controller may transmit an SCE command associated with the first non-volatile memory device NVM1.

At time T12, when the second data burst disable signal DB_DIS_2 is received, the second non-volatile memory device NVM2 may end the memory access operation based on the SCT command associated with the second non-volatile memory device NVM2, and the first non-volatile memory device NVM1 may end the ODT activation operation.

Between time T13 and time T15, while the third data burst enable signal DB_EN_3 is being received, a memory access operation or an ODT activation operation may be performed.

At time T14, the storage controller may transmit an SCT command associated with the first non-volatile memory device NVM1.

At time T15, when the third data burst disable signal DB_DIS_3 is received, the first non-volatile memory device NVM1 may end the memory access operation based on the SCT command associated with the first non-volatile memory device NVM1, and the second non-volatile memory device NVM2 may end the ODT activation operation.

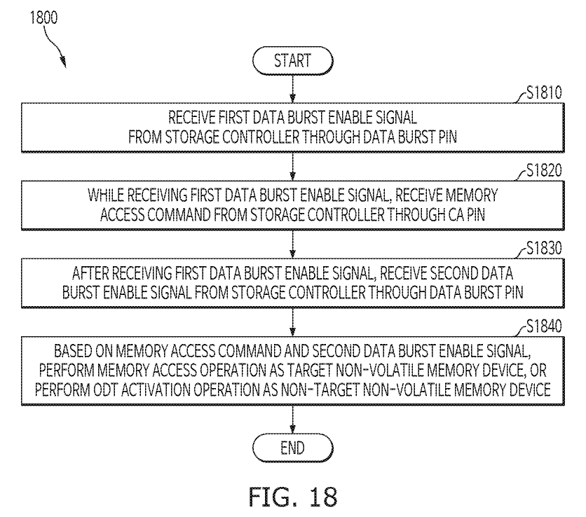

FIG. 18 is a flowchart illustrating a method of operating a non-volatile memory device according to some embodiments of the present disclosure. The method 1800 may be performed by at least one of a plurality of non-volatile memory devices included in a storage device.

Referring to FIG. 18, in step S1810, the non-volatile memory device may receive a first data burst enable signal from the storage controller through a data burst pin.

In step S1820, while receiving the first data burst enable signal, the non-volatile memory device may receive a memory access command from the storage controller through the CA pin. In some embodiments, a non-volatile memory device that has received the memory access command while receiving the first data burst enable signal may be referred to as the target non-volatile memory device associated with the second data burst enable signal. A non-volatile memory device that did not receive a memory access command while receiving the first data burst enable signal may be referred to as the non-target non-volatile memory device associated with the second data burst enable signal.

In step S1830, after receiving the first data burst enable signal, the non-volatile memory device may receive a second data burst enable signal from the storage controller through the data burst pin.

In step S1840, based on the memory access command and the second data burst enable signal, the non-volatile memory device may perform a memory access operation as a target non-volatile memory device or perform an ODT activation operation as a non-target non-volatile memory device.

In some embodiments, the non-volatile memory device may decode the memory access command and, at the time the second data burst enable signal is received, if the non-volatile memory device is a target non-volatile memory device configured to perform a write command, it may control the receiver to perform a write operation, if it is a target non-volatile memory device configured to perform a read command, it may control the transmitter to perform a read operation, and if it is a non-target non-volatile memory device, it may control the transmitter to perform the ODT activation operation.

In some embodiments, the non-volatile memory device may receive a first data burst disable signal between the first data burst enable signal and the second data burst enable signal, and may receive a second data burst disable signal after receiving the second data burst enable signal. Based on the second data burst disable signal, the non-volatile memory device may end the memory access operation as a target non-volatile memory device or end the ODT activation operation as a non-target non-volatile memory device. For example, at the time the second data burst disable signal is received, if the non-volatile memory device is a target non-volatile memory device performing a write command, it may control the receiver to end the write operation, if it is a target non-volatile memory device performing a read command, it may control the transmitter to end the read operation, and if it is a non-target non-volatile memory device, it may control the transmitter to end the ODT activation operation.

The flowchart and description using FIG. 18 are merely an example, and may be implemented differently in some embodiments. For example, in certain embodiments, the order of the steps may be changed, some steps may be repeated, some steps may be omitted, or some steps may be added.

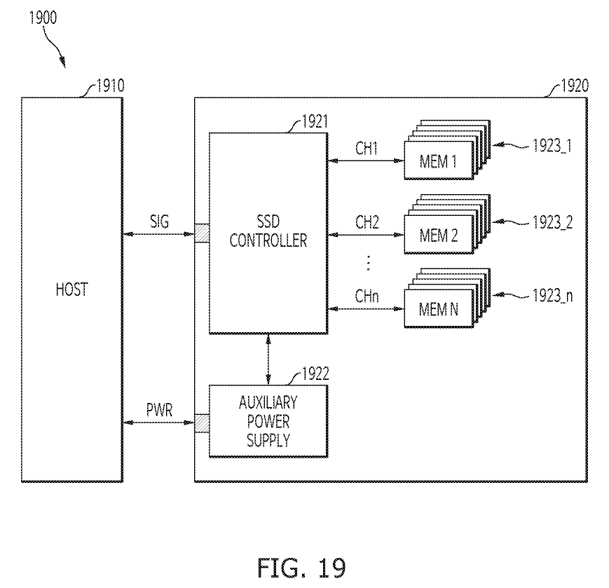

FIG. 19 is a block diagram illustrating an example in which a storage device is applied to an SSD system according to some embodiments of the present disclosure.

Referring to FIG. 19, the SSD system 1900 may include a host 1910 and an SSD 1920. The SSD 1920 may exchange signals SIG with the host 1910 via a signal connector, and may receive power PWR via a power connector. The SSD 1920 may include an SSD controller 1921, an auxiliary power supply 1922, and memory devices 1923_1, 1923_2, and 1923_3. In some embodiments, the memory devices 1923_1, 1923_2, and 1923_3 may be vertically stacked NAND flash memory devices. In this case, the SSD 1920 may be implemented using the embodiments shown in FIGS. 1 through 18.

Herein, the terms indicating order, such as first, second, etc., are used to distinguish elements having the same/similar functions, and the ordinal numbers may be interchanged according to the order in which the terms are mentioned. It will be further understood that the terms “comprises,” “comprising,” “includes” and/or “including,” when used herein, specify the presence of stated features, steps, operations, elements and/or components, but do not preclude the presence or addition of one or more other features, steps, operations, elements, components and/or groups thereof. The term "and/or" includes any and all combinations of one or more of the associated listed items.

What is claimed is:

1. A storage device comprising:
a plurality of non-volatile memory devices, each of the plurality of non-volatile memory devices including a CA (command and address) pin, a data (DQ) pin, and a data burst pin; and
a storage controller configured to transmit a command through the CA pin, transmit and receive data through the data pin, and transmit a data burst enable signal and a data burst disable signal through the data burst pin of one or more of the plurality of non-volatile memory devices,
wherein, among the plurality of non-volatile memory devices, a target non-volatile memory device is configured to perform a memory access operation based on a memory access command received while receiving a first data burst enable signal, and based on a second data burst enable signal,
wherein, among the plurality of non-volatile memory devices, a non-target non-volatile memory device is configured to perform an on-die termination (ODT) activation operation based on the memory access command and the second data burst enable signal, and
wherein the plurality of non-volatile memory devices is configured to receive the second data burst enable signal after receiving the first data burst enable signal.

2. The storage device according to claim 1,
wherein the plurality of non-volatile memory devices is further configured to receive a first data burst disable signal between the first data burst enable signal and the second data burst enable signal, and receive a second data burst disable signal after receiving the second data burst enable signal,
wherein the target non-volatile memory device is further configured to end the memory access operation based on the second data burst disable signal, and
wherein the non-target non-volatile memory device is further configured to end the ODT activation operation based on the second data burst disable signal.

3. The storage device according to claim 2,
wherein the plurality of non-volatile memory devices is further configured to refrain from receiving an additional command from the storage controller through the CA pin of each of the plurality of non-volatile memory devices while receiving the first data burst disable signal.

4. The storage device according to claim 1, wherein each of the plurality of non-volatile memory devices further comprises:
a transmitter and a receiver, wherein the transmitter and the receiver of each of the plurality of non-volatile memory devices are respectively electrically connected to the data pin of each of the plurality of non-volatile memory devices and configured to transmit and receive data to and from the storage controller;
a command decoder of each of the plurality of non-volatile memory devices electrically connected respectively to the CA pin of each of the plurality of non-volatile memory devices, configured to receive the memory access command from the storage controller, and output at least one of a decoded data input command, a decoded data output command, or a decoded ODT command; and
a control block of each of the plurality of non-volatile memory devices electrically connected respectively to the data burst pin of each of the plurality of non-volatile memory devices, configured to receive the at least one decoded command from the command decoder respectively of each of the plurality of non-volatile memory devices, and receive the data burst enable signal and the data burst disable signal through the data burst pin respectively of each of the plurality of non-volatile memory devices.

5. The storage device according to claim 4, wherein the command decoder of each of the plurality of non-volatile memory devices is further configured to:
decode the memory access command;
output a decoded data input command if a respective non-volatile memory device of the plurality of non-volatile memory devices is the target non-volatile memory device configured to perform a write command;
output a decoded data output command if the respective non-volatile memory device is the target non-volatile memory device configured to perform a read command;
and output a decoded ODT command if the respective non-volatile memory device is the non-target non-volatile memory device.

6. The storage device according to claim 5, wherein, while receiving the second data burst enable signal, the control block of each of the plurality of non-volatile memory devices is configured to:
control the receiver respectively of each of the plurality of non-volatile memory devices to perform a write operation if the control block receives the decoded data input command;
control the transmitter respectively of each of the plurality of non-volatile memory devices to perform a read operation if the control block receives the decoded data output command; and
control the transmitter respectively of each of the plurality of non-volatile memory devices to perform the ODT activation operation if the control block receives the decoded ODT command.

7. The storage device according to claim 6, wherein the plurality of non-volatile memory devices is further configured to receive a first data burst disable signal between the first data burst enable signal and the second data burst enable signal, and receive a second data burst disable signal after receiving the second data burst enable signal, and
wherein, in response to receiving the second data burst disable signal, the control block of each of the plurality of non-volatile memory devices is further configured to:
control the receiver respectively of each of the plurality of non-volatile memory devices to end the write operation or control the transmitter respectively of each of the plurality of non-volatile memory devices to end the read operation if the respective non-volatile memory device that includes the control block is the target non-volatile memory device; and
control the transmitter respectively of each of the plurality of non-volatile memory devices to end the ODT activation operation if the respective non-volatile memory device that includes the control block is the non-target non-volatile memory device.

8. The storage device according to claim 5, wherein the control block of each of the plurality of non-volatile memory devices comprises:
a first sub control block configured to control the receiver respectively of each of the plurality of non-volatile memory devices to perform a write operation as the target non-volatile memory device when receiving the second data burst enable signal and the decoded data input command;
a second sub control block configured to control the transmitter respectively of each of the plurality of non-volatile memory devices to perform a read operation as the target non-volatile memory device when receiving the second data burst enable signal and the decoded data output command; and
a third sub control block configured to control the transmitter respectively of each of the plurality of non-volatile memory devices to perform the ODT activation operation as the non-target non-volatile memory device when receiving the second data burst enable signal and the decoded ODT command.

9. The storage device according to claim 4, wherein, after the second data burst enable signal is received, the control block of each of the plurality of non-volatile memory devices is further configured to:
control the receiver respectively of each of the plurality of non-volatile memory devices to perform a write operation if the control block receives the decoded data input command from the command decoder;
control the transmitter respectively of each of the plurality of non-volatile memory devices to perform a read operation if the control block receives the decoded data output command from the command decoder; and
control the transmitter respectively of each of the plurality of non-volatile memory devices to perform the ODT activation operation if the control block receives the decoded ODT command from the command decoder.

10. The storage device according to claim 2, wherein the target non-volatile memory device is further configured to:
receive a select chip enable (SCE) command while receiving the first data burst enable signal;
receive a select chip termination (SCT) command while receiving the second data burst enable signal;
perform a target chip activation operation based on the select chip enable command in response to receiving the second data burst enable signal; and
perform a target chip termination operation based on the select chip termination command after the second data burst disable signal is received.

11. The storage device according to claim 10, wherein the non-target non-volatile memory device is further configured to:
determine, while receiving the first data burst enable signal, whether the select chip enable command is received,
perform the ODT activation operation after the second data burst enable signal is received in response to determining that the select chip enable command is not received,
determine, while receiving the second data burst enable signal, whether the select chip termination command is received, and
end the ODT activation operation after the second data burst disable signal is received in response to determining that the select chip termination command is not received.

12. The storage device according to claim 2, wherein the target non-volatile memory device is further configured to:
further receive a select chip enable command while receiving the first data burst enable signal;
perform a target chip enable operation based on the select chip enable command in response to receiving the second data burst enable signal; and
end the memory access operation in response to receiving the second data burst disable signal.

13. The storage device according to claim 12, wherein the non-target non-volatile memory device is further configured to:
determine, while receiving the first data burst enable signal, whether the select chip enable command is received; and
in response to determining that the select chip enable command is not received, perform the ODT activation operation after the second data burst enable signal is received, and end the ODT activation operation after the second data burst disable signal is received.

14. The storage device according to claim 12, wherein each of the plurality of non-volatile memory devices further comprises:
a transmitter and a receiver, wherein the transmitter and the receiver of each of the plurality of non-volatile memory devices are respectively electrically connected to the data pin of each of the plurality of non-volatile memory devices and configured to transmit and receive data to and from the storage controller;
a command decoder of each of the plurality of non-volatile memory devices electrically connected respectively to the CA pin of each of the plurality of non-volatile memory devices, configured to receive the memory access command and the select chip enable command from the storage controller, and output at least one of a decoded data input command, a decoded data output command, or a decoded ODT command; and
a control block of each of the plurality of non-volatile memory devices electrically connected respectively to the data burst pin of each of the plurality of non-volatile memory devices, configured to receive the at least one decoded command from the command decoder respectively of each of the plurality of non-volatile memory devices, and receive the data burst enable signal and the data burst disable signal through the data burst pin respectively of each of the plurality of non-volatile memory devices,
wherein the command decoder is further configured to:
decode the memory access command and the select chip enable command;
output a decoded data input command if a respective non-volatile memory device of the plurality of non-volatile memory devices is the target non-volatile memory device configured to perform a write command;
output a decoded data output command if the respective non-volatile memory device is the target non-volatile memory device configured to perform a read command; and
output a decoded ODT command if the respective non-volatile memory device is the non-target non-volatile memory device.

15. A non-volatile memory device comprising:
a data input/output circuit configured to transmit and receive data to and from a storage controller through a data (DQ) pin;
a memory cell array including a plurality of memory cells; and
control logic configured to receive a command from the storage controller through a CA pin, and configured to receive a data burst enable signal and a data burst disable signal from the storage controller through a data burst pin,
wherein the control logic is further configured to:
receive a memory access command through the CA pin while receiving a first data burst enable signal through the data burst pin;
after receiving the first data burst enable signal, receive a second data burst enable signal through the data burst pin; and
based on the memory access command and the second data burst enable signal, perform a memory access operation as a target non-volatile memory device or perform an ODT activation operation as a non-target non-volatile memory device.

16. The non-volatile memory device according to claim 15, wherein the control logic is further configured to:
receive a first data burst disable signal between the first data burst enable signal and the second data burst enable signal;
receive a second data burst disable signal after receiving the second data burst enable signal; and
end the memory access operation as the target non-volatile memory device or end the ODT activation operation as the non-target non-volatile memory device based on the second data burst disable signal.

17. The non-volatile memory device according to claim 16, wherein the control logic is further configured to refrain from receiving an additional command from the storage controller through the CA pin while receiving the first data burst disable signal.

18. The non-volatile memory device according to claim 15,
wherein the data input/output circuit comprises a transmitter electrically connected to the data pin and configured to transmit data to the storage controller, and a receiver electrically connected to the data pin and configured to receive data from the storage controller,
wherein the control logic comprises:
a command decoder configured to receive the memory access command through the CA pin and configured to output at least one of a decoded data input command, a decoded data output command, or a decoded ODT command; and
a control block electrically connected to the data burst pin, configured to receive the at least one decoded command from the command decoder, and configured to receive the data burst enable signal and the data burst disable signal from the data burst pin,
wherein, while receiving the second data burst enable signal, the control block is further configured to:
control the receiver to perform a write operation when receiving the decoded data input command;
control the transmitter to perform a read operation when receiving the decoded data output command; and
control the transmitter to perform the ODT activation operation when receiving the decoded ODT command.

19. The non-volatile memory device according to claim 18, wherein the command decoder is configured to:
decode the memory access command received while receiving the first data burst enable signal;
while receiving the second data burst enable signal:
output a decoded data input command if the non-volatile memory device is the target non-volatile memory device configured to perform a write command;
output a decoded data output command if the non-volatile memory device is the target non-volatile memory device configured to perform a read command; and
output a decoded ODT command if the non-volatile memory device is the non-target non-volatile memory device.

20. A method of operating a non-volatile memory device, the method comprising:
receiving, from a storage controller through a data burst pin, a first data burst enable signal;
receiving, from the storage controller through a CA pin while receiving the first data burst enable signal, a memory access command;
receiving, from the storage controller through the data burst pin, a second data burst enable signal after the first data burst enable signal is received; and
based on the memory access command and the second data burst enable signal, performing a memory access operation as a target non-volatile memory device or performing an ODT activation operation as a non-target non-volatile memory device.
